(19) United States
(12) Patent Application Publication
(10) Pub. No.: US 2016/0064479 A1
(43) Pub. Date: Mar. 3, 2016

(54) SEMICONDUCTOR DEVICE AND MANUFACTURING METHOD OF THE SAME

(71) Applicant: MACRONIX International Co., Ltd., Hsinchu (TW)

(72) Inventors: Fang-Hao Hsu, Hsinchu (TW); Hong-Ji Lee, Hsinchu (TW)

(21) Appl. No.: 14/468,832

(22) Filed: Aug. 26, 2014

(51) Int. Cl. H01L 29/06; H01L 21/762

(52) U.S. Cl. CPC H01L 29/0649; H01L 21/76224

(57) ABSTRACT

A semiconductor device and a manufacturing method of the same are provided. The semiconductor device includes a substrate, a first dielectric layer, a first conductive layer, and an isolation structure. The substrate has a trench. The first dielectric layer is disposed on the substrate between two neighboring trenches. The first conductive layer is disposed on the first dielectric layer. The isolation structure, including a step zone and a recessed zone, is disposed in the trench, wherein an upper surface of the step zone is higher than an upper surface of the first dielectric layer.

### BACKGROUND OF THE INVENTION

1. Field of the Invention

The invention relates to a semiconductor device and a manufacturing method of the same.

2. Description of Related Art

As the integration of semiconductor devices increases, the device size continues to decrease. Since the size of each element in the device becomes smaller, the distance between the elements is shortened as well. Generally, the devices are isolated from each other by an isolation structure. Nowadays, the more commonly used isolation structure is a shallow trench isolation (STI) structure. In a memory device, a suitable STI structure can increase the gate coupling ratio (GCR), reduce interference between adjacent memory devices, and at the same time maintain favorable reliability of the memory device.

### SUMMARY OF THE INVENTION

The invention provides a semiconductor device and a manufacturing method thereof for improving a gate coupling ratio (GCR), reducing interference between adjacent memory devices, and maintaining favorable reliability of the semiconductor device.

The invention provides a semiconductor device that includes a substrate, a plurality of first dielectric layers, a plurality of first conductive layers, and a plurality of isolation structures. The substrate has a plurality of trenches. The first dielectric layers are respectively disposed on the substrate between two adjacent trenches. The first conductive layers are disposed on the first dielectric layers. The isolation structures are disposed in the trenches, wherein each of the isolation structures includes a step zone and a recessed zone, and an upper surface of the step zone is higher than an upper surface of the first dielectric layer.

According to an embodiment of the invention, the recessed zone has a U shape, a V shape, a trapezoid shape, a nipple shape, a W shape, or a stepped shape.

According to an embodiment of the invention, a bottom surface of the recessed zone is lower than the upper surface of the step zone and higher than the upper surface of the first dielectric layer.

According to an embodiment of the invention, a width of the recessed zone is in a range of 2 nm to 15 nm.

According to an embodiment of the invention, the recessed zone has a sidewall adjacent to the step zone, and an angle between the sidewall and the upper surface of the step zone is in a range of 5-178 degrees.

According to an embodiment of the invention, the upper surface of the step zone is higher than the upper surface of the first dielectric layer for 200-500 angstroms.

According to an embodiment of the invention, the semiconductor device further includes: a second conductive layer and a second dielectric layer. The second conductive layer is disposed on the first conductive layers and the isolation structures; and the second dielectric layer is disposed between the first conductive layers and the second conductive layer and between the isolation structures and the second conductive layer.

The invention further provides a manufacturing method of a semiconductor device, and the manufacturing method includes: forming a first dielectric layer and a first conductive layer in sequence on a substrate; patterning the first conductive layer and the first dielectric layer and forming a plurality of trenches in the substrate; forming a plurality of isolation material layers in the trenches; removing a portion of the isolation material layers to form a plurality of isolation layers and expose a sidewall of the first conductive layer; and removing a portion of the isolation layers to form a plurality of isolation structures, wherein each of the isolation structures includes a step zone and a recessed zone.

According to an embodiment of the invention, the step of removing the portion of the isolation layers includes: forming a first liner spacer on the sidewall of each first conductive layer; etching the isolation layers with the first liner spacer as a mask; and removing the first liner spacer.

According to an embodiment of the invention, a method of forming the first liner spacer includes: fog ling a first liner layer on the substrate and then anisotropically etching the first liner layer.

According to an embodiment of the invention, a method of etching the isolation layers includes dry etching.

According to an embodiment of the invention, a method of removing the first liner spacer includes wet etching.

According to an embodiment of the invention, the manufacturing method further includes: forming a second liner spacer on a sidewall of the first liner spacer before removing the first liner spacer; etching a portion of the isolation layers with the first liner spacer and the second liner spacer as a mask; and removing the first liner spacer and the second liner spacer.

According to an embodiment of the invention, a method of removing the portion of the isolation material layer includes dry etching.

According to an embodiment of the invention, the manufacturing method further includes forming a second dielectric layer and a second conductive layer in sequence on the substrate.

The semiconductor device and the manufacturing method thereof, provided by the invention, are adapted for improving the gate coupling ratio (GCR), reducing interference between adjacent floating gates, and maintaining favorable reliability of the semiconductor device.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1A to FIG. 1H are schematic cross-sectional views illustrating a manufacturing method of a semiconductor device according to an embodiment of the invention.

FIG. 2 to FIG. 5 are schematic cross-sectional views illustrating semiconductor devices according to other embodiments of the invention.

FIG. 6A to FIG. 6B are schematic cross-sectional views illustrating a manufacturing method of a semiconductor device according to another embodiment of the invention.

FIG. 7A to FIG. 7D are schematic cross-sectional views illustrating a manufacturing method of a semiconductor device according to yet another embodiment of the invention.

### DESCRIPTION OF THE EMBODIMENTS

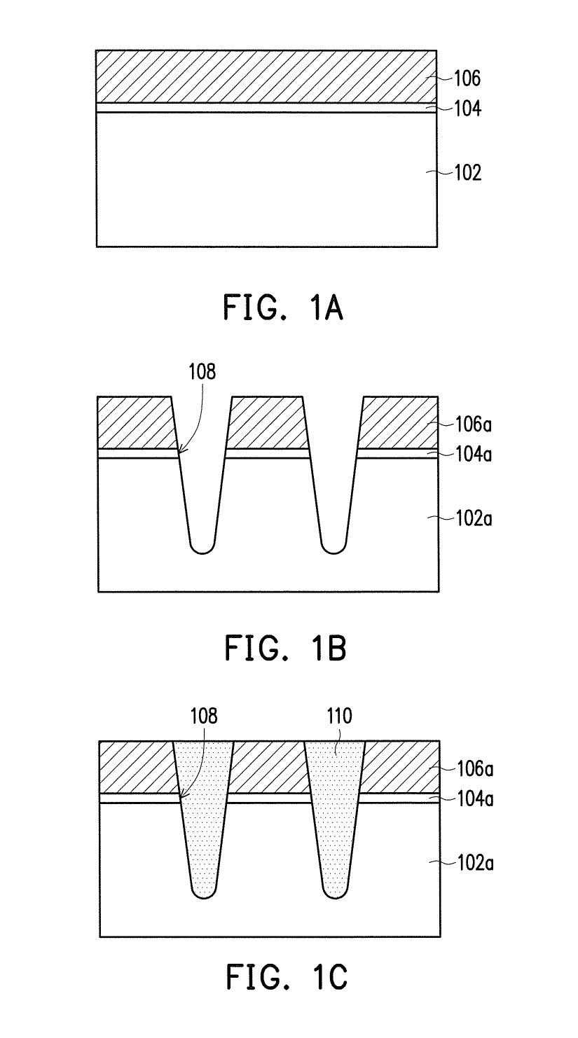

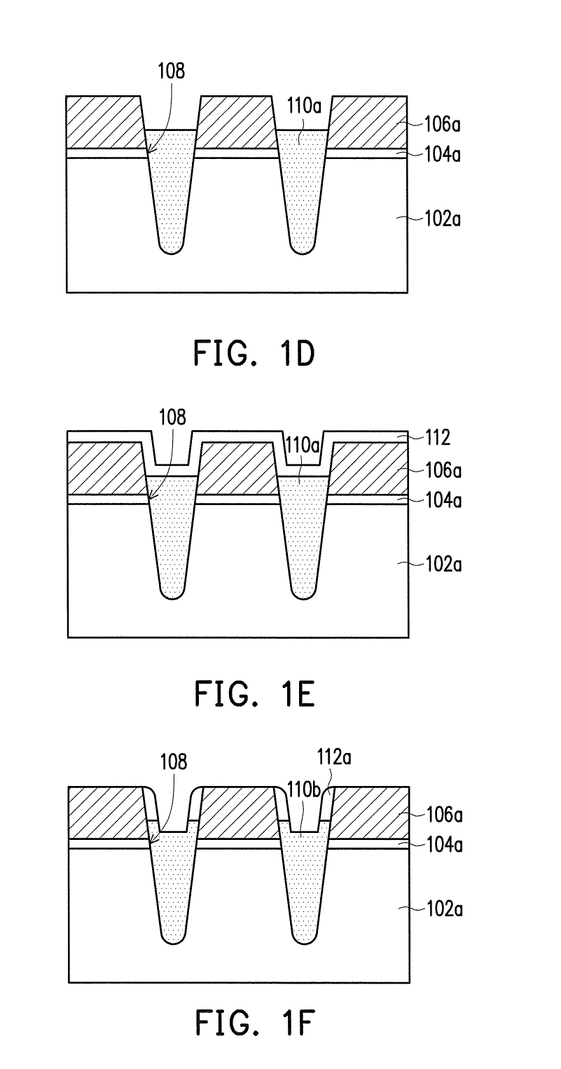

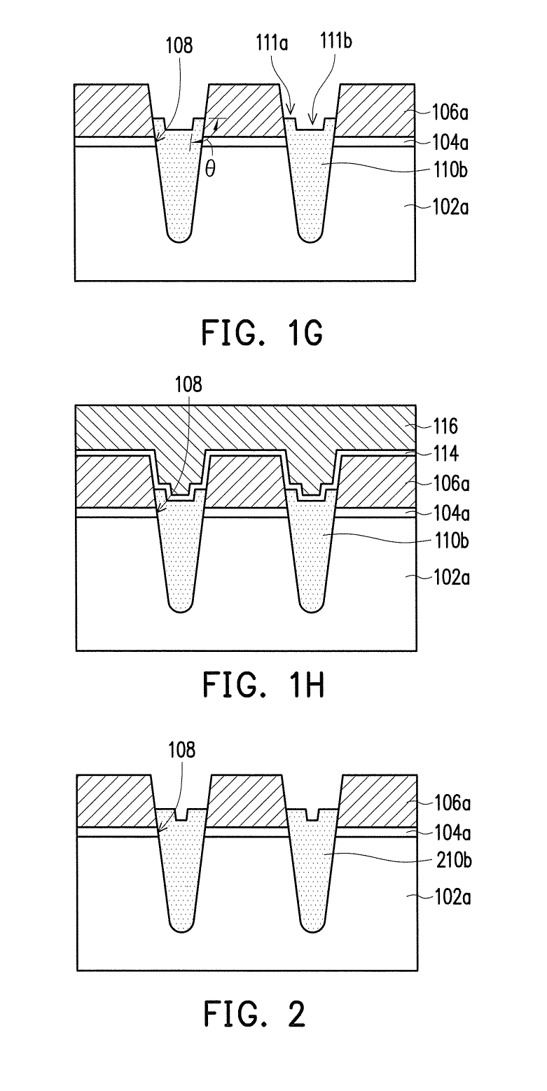

FIG. 1A to FIG. 1H are schematic cross-sectional views illustrating a manufacturing method of a semiconductor device according to an embodiment of the invention.

With reference to FIG. 1A, a first dielectric layer 104 is formed on a substrate 102. The substrate 102 is a semiconductor substrate, a semiconductor compound substrate, or a semiconductor over insulator (SOI) substrate, for example. The semiconductor is IVA group atoms, such as silicon or germanium, for example. The semiconductor compound is formed of IVA group atoms, such as silicon carbide or silicon germanium, or formed of IIIA group atoms and VA group atoms, such as gallium arsenide, for example. The substrate 102 may include a dopant, and the dopant of the substrate 102 may be P type or N type. The P type dopant may be IIIA group ions, such as boron ions. The N type dopant may be VA group ions, such as arsenic or phosphorus.

The first dielectric layer 104 may be a single material layer. The single material layer is a low dielectric constant material or a high dielectric constant material, for example. The low dielectric constant material is a dielectric material having a dielectric constant smaller than 4, such as silicon oxide or silicon oxynitride. The high dielectric constant material is a dielectric material having a dielectric constant greater than 4, such as HfAlO, HfO₂, Al₂O₃, or Si₃N₄. The first dielectric layer may also be a double-layer stack structure or a multi-layer stack structure. The double-layer stack structure is Ruined of a low dielectric constant material and a high dielectric constant material (represented by low dielectric constant material/high dielectric constant material), such as silicon oxide/hafnium silicon oxide, silicon oxide/hafnium oxide or silicon oxide/silicon nitride, for example. The multi-layer stack structure is formed of a low dielectric constant material, a high dielectric constant material, and a low dielectric constant material (represented by low dielectric constant material/high dielectric constant material/low dielectric constant material), such as silicon oxide/silicon nitride/silicon oxide or silicon oxide/aluminum oxide/silicon oxide, for example. A method of forming the first dielectric layer 104 includes thermal oxidation or chemical vapor deposition, for example.

Then, a first conductive layer 106 is formed on the first dielectric layer 104. A material of the first conductive layer 106 is doped polysilicon, polycide, or a stack layer, a metal layer, or an applicable conductor of a combination thereof, for example. A method of forming the first conductive layer 106 includes chemical vapor deposition or physical vapor deposition, for example.

With reference to FIG. 1B, next, the first conductive layer 106 and the first dielectric layer 104 are patterned to form a first conductive layer 106a and a first dielectric layer 104a and form a plurality of trenches 108 in a substrate 102a. A patterning method thereof includes forming a patterned mask layer (not shown) on the first conductive layer 106. The patterned mask layer may be a single material layer or a double material layer. The patterned mask layer is a patterned photoresist layer, for example. Thereafter, an etching process is performed with the patterned mask layer as a mask. The etching process includes anisotropic etching, such as dry etching. Then, the patterned mask layer is removed. A method of removing the patterned mask layer includes dry stripping, wet stripping, or a combination thereof, for example.

With reference to FIG. 1C, thereafter, an isolation material layer 110 is formed in the trenches 108. A method of forming the isolation material layer 110 includes forming an insulation material in the trenches 108 and on the first conductive layer 106a. The insulation material is silicon oxide or borophosphosilicate glass, for example. A method of forming the insulation material includes chemical vapor deposition, for example. Then, the insulation material on the first conductive layer 106a is removed by performing chemical mechanical polishing (CMP) or etch-back.

With reference to FIG. 1C and FIG. 1D, then, a portion of the isolation material layer 110 in the trenches 108 is removed by performing an etch-back process so as to form an isolation layer 110a. An upper surface of the isolation layer 110a is lower than an upper surface of the first conductive layer 106a and higher than an upper surface of the first dielectric layer 104a and exposes a sidewall of the first conductive layer 106a. In an embodiment, a distance between the upper surface of the isolation layer 110a and the upper surface of the first dielectric layer 104a is about 200-500 angstroms. A method of removing the portion of the isolation material layer 110 includes dry etching, for example.

With reference to FIG. 1E, next, a liner material layer 112 is formed on the substrate 102a to cover the first conductive layer 106a, the sidewall of the first conductive layer 106a, and the isolation material layer 110a. A material of the liner material layer 112 is different from a composition material of the isolation material layer 110. The liner material layer 112 may be a single layer or include multiple layers. The material of the liner material layer 112 includes oxide, nitride, oxynitride, or carbo-oxy-nitride, such as silicon oxide, silicon nitride, silicon oxynitride, or silicon carbo-oxy-nitride (SCON). A method of forming the liner material layer 112 includes low-temperature thermal oxidation, thermal oxidation, atomic layer deposition, or chemical vapor deposition, for example. A thickness of the liner material layer 112 is in a range of 1 nm to 20 nm, for example.

With reference to FIG. 1F, thereafter, a portion of the liner material layer 112 is removed by performing an anisotropic etching process, so as to form a liner spacer 112a on the sidewall of each first conductive layer 106a. Then, the isolation layer 110a is removed by performing the etch-back process again with the liner spacer 112a as a mask so as to form an isolation structure 110b. A method of removing the isolation layer 110a includes dry etching, for example.

With reference to FIG. 1G, next, the liner spacer 112a is removed to expose an upper surface of the isolation structure 110b in the trench 108. A method of removing the liner spacer 112a includes wet etching using hydrofluoric acid, for example. Each of the isolation structures 110b includes a step zone 111a and a recessed zone 111b. An upper surface of the step zone 111a is higher than an upper surface of the recessed zone 111b for 200-500 angstroms. A bottom surface of the recessed zone 111b is lower than the upper surface of the step zone 111a and higher than the upper surface of the first dielectric layer 104a. In an embodiment, a width of the recessed zone 111b is in a range of 2 nm to 15 nm and the recessed zone 111b has a sidewall adjacent to the step zone 111a. An angle θ between the sidewall and the upper surface of the step zone 111a is in a range of 5-178 degrees.

With reference to FIG. 1H, then, a second dielectric layer 114 and a second conductive layer 116 are formed in sequence on the substrate 102a. The second dielectric layer 114 may be a single layer or include multiple layers. A material of the second dielectric layer 114 includes silicon oxide, silicon nitride, or other insulation materials. A method of forming the second dielectric layer 114 includes chemical vapor deposition, for example. A material of the second conductive layer 116 may be the same as or different from the material of the first conductive layer 106a, such as doped polysilicon, polycide, or a stack layer, a metal layer, or an applicable conductor of a combination thereof, for example. A forming method thereof includes chemical vapor deposition or physical vapor deposition, for example.

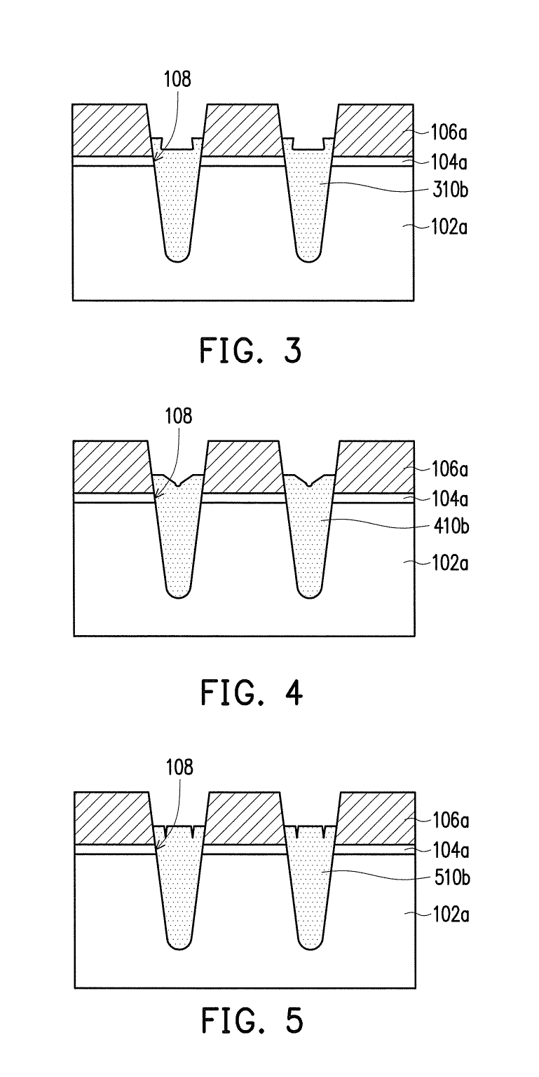

In other embodiments of the invention, the recessed zone may be formed in other shapes. In addition to the U shape illustrated in FIG. 1G, the recessed zone may have a V shape (FIG. 2), a trapezoid shape (FIG. 3), a nipple shape (FIG. 4), or a W shape (FIG. 5) by controlling an etching condition, a thickness of the liner spacer, etc.

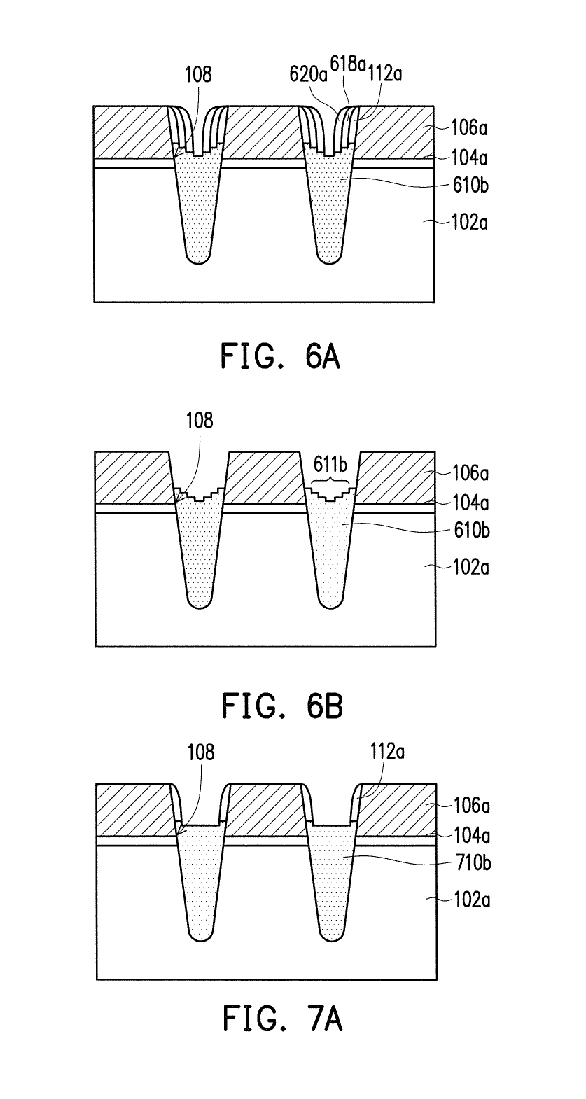

FIG. 6A to FIG. 6B are schematic cross-sectional views illustrating a manufacturing method of a semiconductor device according to another embodiment of the invention.

With reference to FIG. 6A and FIG. 6B, in another embodiment of the invention, a first liner spacer 112a, a second liner spacer 618a, and a third liner spacer 620a are formed in sequence on the sidewall of the first conductive layer 106a. After forming the first liner spacer 112a, the second liner spacer 618a, and the third liner spacer 620a, the isolation layer is etched respectively to form a stepped isolation structure. More specifically, the first liner spacer 112a is formed on the sidewall of the first conductive layer 106a, and the isolation layer is etched with the first liner spacer 112a as a mask. Next, the second liner spacer 618a is formed on a sidewall of the first liner spacer 112a, and the isolation layer is etched again with the first liner spacer 112a and the second liner spacer 618a as a mask. Thereafter, the third liner spacer 620a is formed on a sidewall of the second liner spacer 618a, and the isolation layer is etched again with the first liner spacer 112a, the second liner spacer 618a, and the third liner spacer 620a as a mask. Then, the first liner spacer 112a, the second liner spacer 618a, and the third liner spacer 620a are removed to from an isolation structure 610b having a stepped recessed zone 611b (FIG. 6B).

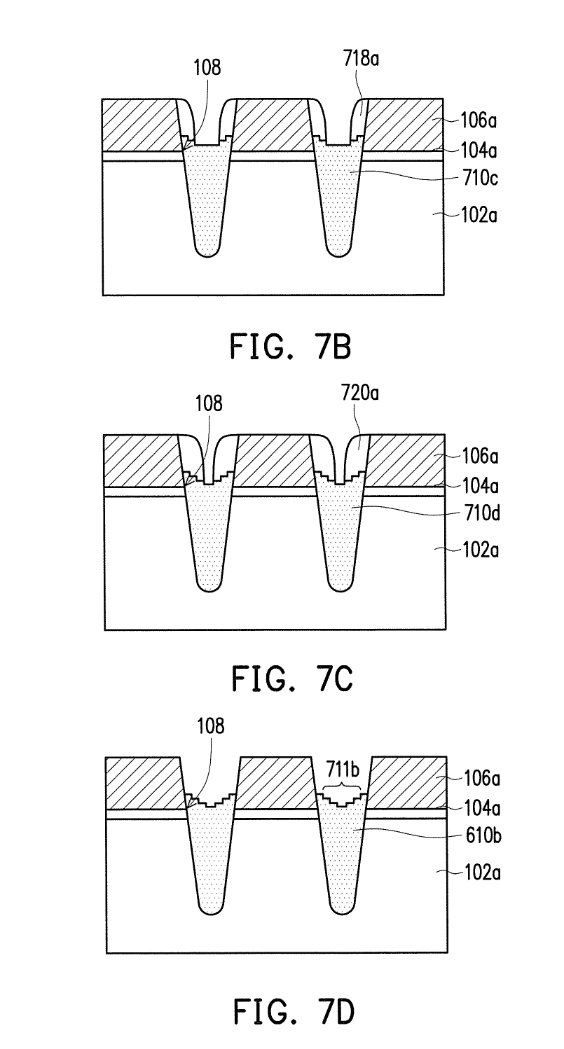

FIG. 7A to FIG. 7D are schematic cross-sectional views illustrating a manufacturing method of a semiconductor device according to yet another embodiment of the invention.

With reference to FIG. 7A, in another embodiment, the first liner spacer 112a is formed on the sidewall of the first conductive layer 106a, and the isolation layer is etched with the first liner spacer 112a as a mask so as to form an isolation layer 710b having a one-step recessed zone.

With reference to FIG. 7A and FIG. 7B, next, the first liner spacer 112a is removed. A second liner spacer 718a is then formed on the sidewall of the first conductive layer 106a, and the isolation layer 710b is etched again with the second liner spacer 718a as a mask, so as to form an isolation layer 710c having a two-step recessed zone.

With reference to FIG. 7B and FIG. 7C, thereafter, the second liner spacer 718a is removed. A third liner spacer 720a is then formed on the sidewall of the first conductive layer 106a, and the isolation layer 710c is etched again with the third liner spacer 720a as a mask, so as to form an isolation structure 710d having a three-step recessed zone.

With reference to FIG. 7C and FIG. 7D, then, the third liner spacer 720a is removed to expose the isolation structure 710d having the three-step recessed zone 711b.

With reference to FIG. 1H again, the semiconductor device of the embodiment of the invention is disposed on the substrate 102 and includes the first conductive layer 106a, the first dielectric layer 104a, the isolation structure 110b, the second dielectric layer 114, and the second conductive layer 116.

The substrate 102 includes a plurality of trenches 108. The first dielectric layers 104a are respectively disposed on the substrate 102 between two adjacent trenches 108. The first dielectric layer 104a may serve as a tunneling dielectric layer. The first conductive layer 106a is disposed on the first dielectric layer 104a to serve as a floating gate of the semiconductor device.

The second conductive layer 116 covers the first conductive layer 106a and covers the isolation structure 110b and may serve as a control gate of the semiconductor device. The second dielectric layer 114 is disposed between the first conductive layer 106a and the second conductive layer 116 and between the isolation structure 110b and the second conductive layer 116 to serve as an inter-gate dielectric layer.

A plurality of the isolation structures 110b are disposed in the trenches 108 of the substrate 102a on two sides of the first conductive layer 106a for isolating two adjacent devices from each other. Each of the isolation structures 110b includes the step zone 111a and the recessed zone 111b. The upper surface of the step zone 111a is higher than the upper surface of the first dielectric layer 104a for 200-500 angstroms. The bottom surface of the recessed zone 111b is lower than the upper surface of the step zone 111a and higher than the upper surface of the first dielectric layer 104a. The recessed zone 111b may have a U shape, a V shape, a trapezoid shape, a nipple shape, a W shape, or a stepped shape. The width of the recessed zone 111b is in a range of 2 nm to 15 nm, and the recessed zone 111b has the sidewall adjacent to the step zone 111a. An angle θ between the sidewall and the upper surface of the step zone 111a is in a range of 5-178 degrees.

To sum up, according to the invention, the isolation structure having the recessed zone is formed by forming the liner spacers and performing the etching processes during the fabrication, so as to improve the gate coupling ratio, reduce the interference between adjacent floating gates, and at the same time maintain favorable reliability. In addition, the fabricating process of the invention can be integrated with the existing processes.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

1. A semiconductor device, comprising:
a substrate comprising a plurality of trenches;
a plurality of first dielectric layers respectively disposed on the substrate between two adjacent trenches;
a plurality of first conductive layers disposed on the first dielectric layers; and
a plurality of isolation structures disposed in the trenches, wherein each of the isolation structures comprises a step zone and a recessed zone, and an upper surface of the step zone is higher than an upper surface of the first dielectric layer.

2. The semiconductor device according to claim 1, wherein the recessed zone has a U shape, a V shape, a trapezoid shape, a nipple shape, a W shape, or a stepped shape.

3. The semiconductor device according to claim 1, wherein a bottom surface of the recessed zone is lower than the upper surface of the step zone and higher than the upper surface of the first dielectric layer.

4. The semiconductor device according to claim 1, wherein a width of the recessed zone is in a range of 2 nm to 15 nm.

5. The semiconductor device according to claim 1, wherein the recessed zone comprises a sidewall adjacent to the step zone, and an angle between the sidewall and the upper surface of the step zone is in a range of 5-178 degrees.

6. The semiconductor device according to claim 1, wherein the upper surface of the step zone is higher than the upper surface of the first dielectric layer for 200-500 angstroms.

7. The semiconductor device according to claim 1, further comprising:
a second conductive layer disposed on the first conductive layers and the isolation structures; and
a second dielectric layer disposed between the first conductive layers and the second conductive layer and between the isolation structures and the second conductive layer.

8. A manufacturing method of a semiconductor device, the manufacturing method comprising:
forming a first dielectric layer and a first conductive layer in sequence on a substrate;
patterning the first conductive layer and the first dielectric layer and forming a plurality of trenches in the substrate;
forming a plurality of isolation material layers in the trenches;
removing a portion of the isolation material layers to form a plurality of isolation layers and expose a sidewall of the first conductive layer; and
removing a portion of the isolation layers to form a plurality of isolation structures, wherein each of the isolation structures comprises a step zone and a recessed zone.

9. The manufacturing method according to claim 8, wherein the step of removing the portion of the isolation layers comprises:
forming a first liner spacer on the sidewall of each first conductive layer;
etching the isolation layers with the first liner spacer as a mask; and
removing the first liner spacer.

10. The manufacturing method according to claim 9, wherein a method of forming the first liner spacer comprises:
forming a first liner layer on the substrate; and
anisotropically etching the first liner layer.

11. The manufacturing method according to claim 9, wherein a method of etching the isolation layers comprises dry etching.

12. The manufacturing method according to claim 9, wherein a method of removing the first liner spacer comprises wet etching.

13. The manufacturing method according to claim 9, further comprising:
forming a second liner spacer on a sidewall of the first liner spacer before removing the first liner spacer;
etching the isolation layers with the first liner spacer and the second liner spacer as a mask; and
removing the first liner spacer and the second liner spacer.

14. The manufacturing method according to claim 8, wherein a method of removing the portion of the isolation material layer comprises dry etching.

15. The manufacturing method according to claim 8, further comprising:
forming a second dielectric layer and a second conductive layer in sequence on the substrate.
